(19) United States
(12) Patent Application Publication
(10) Pub. No.: US 2024/0162118 A1
(43) Pub. Date: May 16, 2024

(54) BACKSIDE SKIP-LEVEL THROUGH VIA FOR BACKSIDE SIGNAL LINE CONNECTION

(71) Applicant: International Business Machines Corporation, Armonk, NY (US)

(72) Inventors: Ruilong Xie, Niskayuna, NY (US); Biswanath Senapati, Mechanicville, NY (US); David Wolpert, Poughkeepsie, NY (US); Nicholas Anthony Lanzillo, Wynantskill, NY (US); Lawrence A. Clevenger, Saratoga Springs, NY (US); Leon Sigal, Monsey, NY (US)

(21) Appl. No.: 17/986,276

(22) Filed: Nov. 14, 2022

(51) Int. Cl. H01L 23/48; H01L 23/528; H01L 27/092; H01L 29/06; H01L 29/423; H01L 29/775

(52) U.S. Cl. CPC H01L 23/481; H01L 23/5286; H01L 27/092; H01L 29/0673; H01L 29/42392; H01L 29/775

(57) ABSTRACT

A semiconductor structure is provided that includes a gate structure that is wired to a backside signal line through a backside gate contact extension and a backside skip-level through via. The backside skip-level through via has a dielectric spacer located on a sidewall thereof and a portion of the backside skip-level through via is positioned between a pair of backside power rails that are located in a first backside metal level that is located beneath a second backside metal level that includes the backside signal line.

### BACKGROUND

The present application relates to semiconductor technology, and more particularly to a semiconductor structure including a backside skip-level through via that provides an electrical connection between a gate structure and a backside signal line.

When forming a structure including a plurality of complementary metal oxide semiconductor (CMOS) devices, such as integrated circuits, standard cells can be used as a base unit for designing and manufacturing the integrated circuits. The standard cell(s) can be used to form one or more functional circuits, and each standard cell can have the same footprint. Using standard cells when designing complex circuits and components reduces design and manufacture costs.

In use, each standard cell of a semiconductor structure requires power input (Vdd) and ground (Vss) connections. To power the various components thereof, each standard cell is generally coupled to a backside power rail which is electrically connected to an active layer of the standard cell to provide the power (Vdd). In some instances, a plurality of backside power rails may be provided for each standard cell to respectively provide the power (Vdd) and the ground (Vss).

Backside power rails are typically formed on the backside of the wafer. Such backside power rails are connected to a source/drain region of a field effect transistor (FET) utilizing a via-to-backside power rail (VBPR) contact structure. In some instances, a backside signal line is also present in the backside, and in such instances, the backside signal line and the backside power rails are typically present in a first backside metal level. By adding the backside signal line to the first backside metal level including the backside power rails, the pitch of the first backside metal level has to reduce to half. This reduced pitch can cause a higher risk of first backside metal level to VBPR open, and thus cause an increased resistance of the first backside metal level.

### SUMMARY

A semiconductor structure is provided that includes a gate structure that is wired to a backside signal line through a backside gate contact extension and a backside skip-level through via. The backside skip-level through via has a dielectric spacer located on a sidewall thereof and a portion of the backside skip-level through via is positioned between a pair of backside power rails that are located in a first backside metal level that is located beneath a second backside metal level that includes the backside signal line.

In one aspect of the present application, a semiconductor structure is provided. In one embodiment, the semiconductor structure includes a gate structure having a backside gate contact extension, a first backside metal level including a pair of spaced apart backside power rails and located beneath the backside gate contact extension of the gate structure, a second backside metal level including a backside signal line and located on the first backside metal level, and a backside skip-level through via connecting the backside signal line to the backside gate contact extension of the gate structure. Such a structure has a low first backside metal level resistance.

In another aspect of the present application, a method of forming the semiconductor structure mentioned above is provided. The method of the present application which includes both frontside and backside processing will be described in greater detail herein below.

### BRIEF DESCRIPTION OF THE DRAWINGS

FIG. 1 is a top down view showing a device layout that can be employed in the present application, the device layout includes a plurality of gate structures located in an nFET device region, a pFET device region, a region located between the nFET and pFET device regions, and cuts X1-X1, X2-X2, Y1-Y1, and Y2-Y2.

FIGS. 2A, 2B, 2C and 2D are cross sectional views through cuts X1-X1, X2-X2, Y1-Y1, and Y2-Y2 shown in FIG. 1, respectively, of an exemplary structure that can be employed in the present application, the exemplary structure including at least one gate structure having a backside gate contact extension, the at least one gate structure is a continuous structure that is present in an nFET device region, a pFET device region and in a region that is located between the nFET device region and the pFET device region.

FIGS. 3A, 3B, 3C and 3D are cross sectional views of the exemplary structure shown in FIGS. 2A, 2B, 2C and 2D, respectively, after flipping the structure 180° to physically expose a backside of the substrate.

FIGS. 4A, 4B, 4C and 4D are cross sectional views of the exemplary structure shown in FIGS. 3A, 3B, 3C and 3D, respectively, after removing a first semiconductor material layer of the substrate to physically expose an etch stop layer of the substrate.

FIGS. 5A, 5B, 5C and 5D are cross sectional views of the exemplary structure shown in FIGS. 4A, 4B, 4C and 4D, respectively, after removing the physically exposed etch stop layer of the substrate to physically expose a second semiconductor material layer of the substrate.

FIGS. 6A, 6B, 6C and 6D are cross sectional views of the exemplary structure shown in FIGS. 5A, 5B, 5C and 5D, respectively, after recessing the physically exposed second semiconductor layer of the substrate to physically expose a surface of the backside gate contact extension.

FIGS. 7A, 7B, 7C and 7D are cross sectional views of the exemplary structure shown in FIGS. 6A, 6B, 6C and 6D, respectively, after forming a first backside interlayer dielectric material layer.

FIGS. 8A, 8B, 8C and 8D are cross sectional views of the exemplary structure shown in FIGS. 7A, 7B, 7C and 7D, respectively, after forming spaced apart backside power rails in the first backside interlayer dielectric material.

FIGS. 9A, 9B, 9C and 9D are cross sectional views of the exemplary structure shown in FIGS. 8A, 8B, 8C and 8D, respectively, after forming a second backside interlayer dielectric material layer.

FIGS. 10A, 10B, 10C and 10D are cross sectional views of the exemplary structure shown in FIGS. 9A, 9B, 9C and 9D, respectively, after forming a backside skip-level via opening in the second backside interlayer dielectric material layer and the first backside interlayer dielectric material layer, the backside skip-level via opening physically exposing a surface of the backside gate contact extension.

FIGS. 11A, 11B, 11C and 11D are cross sectional views of the exemplary structure shown in FIGS. 10A, 10B, 10C and 10D, respectively, after forming a dielectric spacer in the backside skip-level via opening and along physically exposed sidewalls of the second backside interlayer dielectric material layer and the first backside interlayer dielectric material layer.

FIGS. 12A, 12B, 12C and 12D are cross sectional views of the exemplary structure shown in FIGS. 11A, 11B, 11C and 11D, respectively, after forming a backside skip-level through via and a metal via structure, and a third backside interlayer dielectric material layer including a backside signal line contacting the backside skip-level through via and an electrically conductive structure contacting the metal via structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In the present application, chemical elements can be referred to using their chemical symbol from the Periodic Table of Elements. For example, aluminum can be referred to as “Al”, tungsten can be referred to as “W”, copper can be referred to as “Cu”, etc.

As mentioned above, and in one aspect of the present application, a semiconductor structure is provided that includes a gate structure having a backside gate contact extension, a first backside metal level including spaced apart backside power rails and located beneath the backside gate contact extension of the gate structure, a second backside metal level including a backside signal line and located on the first backside metal level, and a backside skip-level through via connecting the backside signal line to the backside gate contact extension of the gate structure. Such a structure has a low first backside metal level resistance. This structure and the method of forming the same will now be described in greater detail.

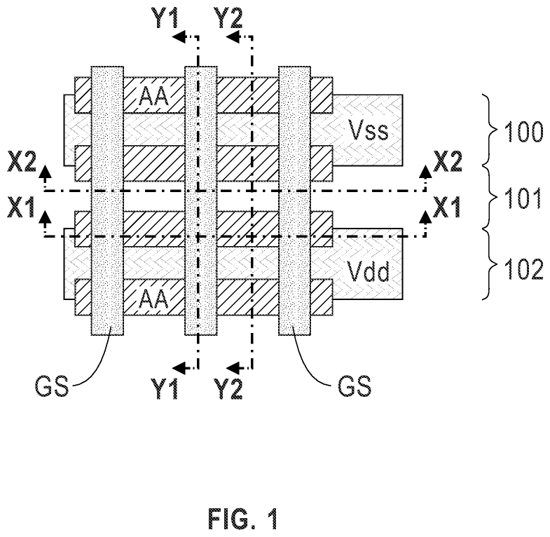

Reference is first made to FIG. 1, which is a top down view showing a device layout that can be employed in the present application, the device layout includes three gate structures, GS, that are orientated parallel to each other and each gate structure is present in an nFET device region 100, a pFET device region 102 and a region 101 that is located between the nFET device region 100 and the pFET device region 102. Each of nFET device region 100 and adjacent pFET device region 102 includes an active area, AA, in which each of the gate structure, GS, is present thereon. The illustrated device layout shown in FIG. 1 also includes a backside power rail that can supply Vss power to each of the FETs present in the nFET device region 100, and another backside power rail that can supply Vdd power to each of the FETs present in the pFET device region 102. In the present application, the terms “field effect transistor” or “FET” for short, denote a three terminal device that includes at least one semiconductor material channel structure, a gate structure contacting the at least one semiconductor material channel structure, and source/drain regions located on each side of the gate structure.

In region 101 of the present application, a common gate structure is present that extends into the nFET device region 100 and the pFET device region 102. Within the nFET device region 100, the common gate structure has a portion that contacts at least one semiconductor material channel material structure and thus forms a first nFET, while within the pFET device region 102, the common gate structure has a portion that contacts at least one semiconductor material channel material structure and thus forms a first pFET.

The illustrated device layout also includes cuts X1-X1, X2-X2, Y1-Y1, and Y2-Y2. Cut X1-X1 is in a direction perpendicular to each gate structure, GS, and this cut passes through the pFET device region 102. Cut X2-X2 is in a direction perpendicular to each gate structure, GS, and this cut is in the area 101 that is located between the nFET device region 100 and the pFET device region 102. Cut Y1-Y1 is through the middle gate structure shown in FIG. 1. Cut Y2-Y2 is in a region between the middle gate structure and gate structure that to the right of the middle gate structure shown in FIG. 1; a portion of Y2-Y2 is in an area in which source/drain regions will be formed.

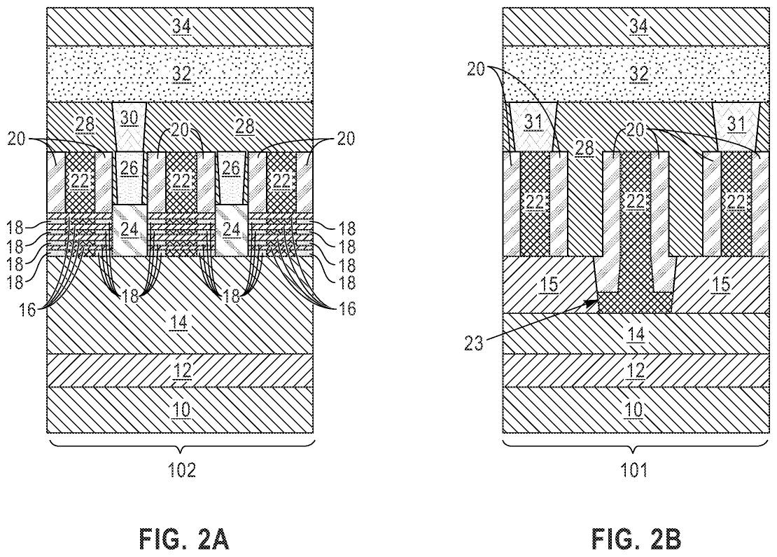

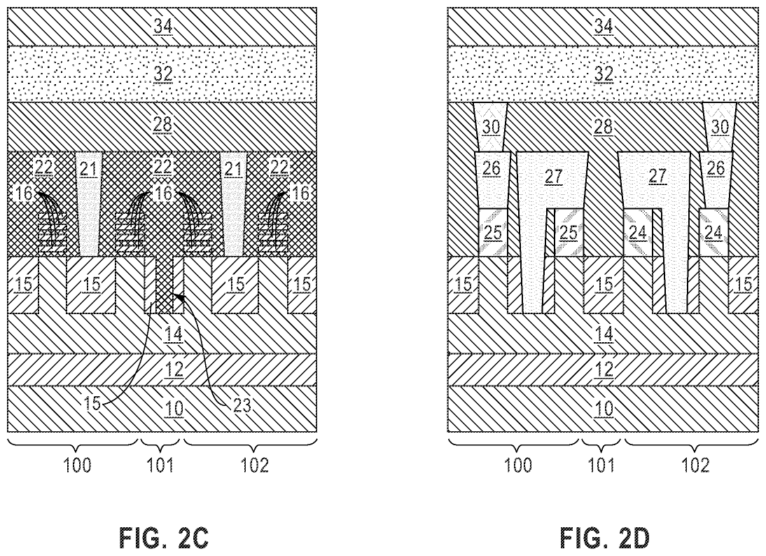

In the present application, each of FIGS. 2A, 3A, 4A, 5A, 6A, 7A, 8A, 9A, 10A, 11A and 12A is through X1-X1 shown in FIG. 1; note a similar structure would also be present in the nFET device region 100. Each of FIGS. 2B, 3B, 4B, 5B, 6B, 7B, 8B, 9B, 10B, 11B and 12B is through cut X2-X2 shown in FIG. 1, each of FIGS. 2C, 3C, 4C, 5C, 6C, 7C, 8C, 9C, 10C, 11C and 12C is through cut Y1-Y1 shown in FIG. 1, and each of FIGS. 2D, 3D, 4D, 5D, 6D, 7D, 8D, 9D, 10D, 11D and 12D is through cut Y2-Y2 shown in FIG. 1. Throughout the present application, that at least one gate structure having the extension region is present in region 101; i.e., the region between the nFET device region 100 and the pFET device region 102.

Referring now FIGS. 2A, 2B, 2C and 2D, there are illustrated through the various cuts shown in FIG. 1 an exemplary structure that can be employed in the present application. The exemplary structure includes at least one gate structure 22 having a backside gate contact extension 23. The at least one gate structure 22 having the backside gate contact extension 23 is present in region 101 and it is a continuous gate structure that extends into both the nFET device region 100 and the pFET device region 102, See, for example, FIGS. 2A and 2C. Three gate structures 22 are shown by way of one example in FIGS. 2A-2D of the present application, and these three gate structures 22 correlate to the three gate structures GS shown in FIG. 1. In the illustrated embodiment of the present application, the middle gate structure shown in the drawings has the backside gate extension, while the other two gate structures do not. Other structures are possible in which more than one gate structure 22 having the backside gate contact extension 23 is present.

The illustrated structure shown in FIGS. 2A-2D further includes a shallow trench isolation structure 15, a plurality of vertically stacked semiconductor channel material nanosheets 16, inner gate spacers 18, a gate spacer 20, a dielectric material pillar 21, pFET device source/drain regions 24, nFET device source/drain regions 25, via-to-backside power rail (VBPR) contact structures 27, a frontside interlayer dielectric (ILD) material layer 28, source/drain contact structures 26, first frontside metal via structures 30, second frontside metal via structures 31, a frontside back-end-of-the-line (BEOL) structure 32 and a carrier wafer 34 configured as shown in FIGS. 2A-2D. The exemplary structure shown in FIGS. 2A-2D can be formed utilizing conventional front-end-line (FEOL) device processing, conventional middle-of-the-line (MOL) device processing, and conventional BEOL device processing, each of which is well known to those skilled in the art. The FEOL device processing, MOL device processing and BEOL device processing can include, for example, various deposition steps, patterning steps and/or metallization steps. The carrier wafer 34 is bonded to the frontside BEOL structure 32 after the frontside BEOL structure 32 has been formed on the first frontside ILD material layer 28. The various elements/components of the exemplary structure shown in FIGS. 2A-2D will now be described in greater detail.

In the present application, the substrate typically includes a first semiconductor material layer 10, an etch stop layer 12 and a second semiconductor material layer 14. The first semiconductor material layer 10 of the semiconductor substrate is composed of a first semiconductor material having semiconducting properties. Examples of first semiconductor materials that can be used to provide the first semiconductor material layer 10 include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material layer 14 of the semiconductor substrate is composed of a second semiconductor material. The second semiconductor material that provides the second semiconductor material layer 14 can be compositionally the same as, or compositionally different from, the first semiconductor material that provides the first semiconductor material layer 10. In some embodiments of the present application, the etch stop layer 12 can be composed of a dielectric material such as, for example, silicon dioxide and/or boron nitride. In other embodiments of the present application, the etch stop layer 12 is composed of a semiconductor material that is compositionally different from the semiconductor material that provides both the first semiconductor material layer 10 and the second semiconductor material layer 14. In one example, the first semiconductor material layer 10 is composed of silicon, the etch stop layer 12 is composed of silicon dioxide, and the second semiconductor material layer 14 is composed of silicon. Such a semiconductor substrate including silicon/silicon dioxide/silicon can be referred to as a silicon-on-insulator (SOI) substrate. In another example, the first semiconductor material layer 10 is composed of silicon, the etch stop layer 12 is composed of silicon germanium, and the second semiconductor material layer 14 is composed of silicon. Such a semiconductor substrate including silicon/silicon germanium/silicon can be referred to as a bulk semiconductor substrate. Other substrates including at least one semiconductor material are possible can also be employed in the present application.

The shallow trench isolation structure 15 is composed of any trench dielectric material such as, for example, silicon oxide. In some embodiments, a trench dielectric material liner such as, for example, a SiN liner, can be present along a sidewall and a bottom wall of the trench dielectric material. As is illustrated in FIGS. 2B and 2C, the backside gate contact extension 23 is located in an opening in the shallow trench isolation structure 15 such that the backside gate contact extension 23 lands on a recessed surface of the second semiconductor material layer 14. Also, and is illustrated in FIGS. 2C and 2D, the shallow trench isolation structure 15 is located within the second semiconductor material layer 14 and it is located laterally adjacent to a non-recessed (i.e., mesa) portion of the second semiconductor material layer 14.

Each semiconductor channel material nanosheet 16 is composed of one of the semiconductor materials mentioned above for the first semiconductor material layer 10. In one example, each semiconductor channel material nanosheet 16 is composed of Si or SiGe. In some embodiments, the semiconductor channel material nanosheets 16 that are located in the nFET device region 100 are compositionally the same as the semiconductor channel material nanosheets 16 that are located in the pFET device region 102. In other embodiments, the semiconductor channel material nanosheets 16 that are located in the nFET device region 100 are compositionally different from the semiconductor channel material nanosheets 16 that are located in the pFET device region 102. For example, each semiconductor channel material nanosheet 16 in the nFET device region 100 can be composed of a semiconductor material that is capable of providing high channel mobility for nFET devices, while each semiconductor channel material nanosheet 16 in the pFET device region 102 can be composed of a semiconductor material that is capable of providing high channel mobility for pFET devices. Each semiconductor channel material nanosheet 16 typically has a width from 6 nm to 100 nm, a vertical height from 4 nm to 15 nm. In the present application and within the respective device regions, the gate structure 22 wraps around each of the semiconductor channel material nanosheets 16. It is noted that the semiconductor channel material nanosheets 16 are semiconductor channel material structures used in providing nano-sheet containing FET devices. Although the present application describes and illustrates nanosheets as the semiconductor channel material structures, the present application works with other types of semiconductor channel material structures including, but not limited to, semiconductor Fin channel structures (used for providing FinFETs), vertical semiconductor channel pillars (used for providing vertical FETs), semiconductor nanowires (used for providing nanowire containing FETs), or any combination thereof with or without the nanosheets.

The inner gate spacers 18 are located beneath, and at an end portion of, each semiconductor channel material nanosheet 16. The inner gate spacers 18 are composed of a spacer dielectric material including, but not limited to, SiN, SiBCN, SiOCN, SiON or SiOC.

Gate spacer 20, which is present along a sidewall of the gate structures 22 as well as a portion of the backside gate contact extension 23, can also be composed of a spacer dielectric material. The spacer dielectric material that provides the gate spacer 20 can be compositionally the same as, or compositionally different from, the dielectric spacer material that provides the inner gate spacers 18. The gate spacer 20 typically has a topmost surface that is coplanar with a topmost surface of each gate structure 22.

Dielectric material pillar 21 is used in embodiments of the present application to cut the gate structure 22 in each of the device regions, and to provide multiple FETs from each gate structure 22. In some embodiments, the dielectric material pillar 21 can be omitted from both device regions, or the dielectric material pillar 21 can be omitted from one of the device regions, but not the other device region. When present, the dielectric material pillar 21 lands on a surface of the shallow trench isolation structure 15 and the dielectric material pillar 21 has a topmost surface that is typically coplanar with a topmost surface of the gate structures 22. The dielectric material pillar 21 can be composed of any dielectric material such as, for example, one of the spacer dielectric materials mentioned above. Dielectric material pillar 21 can have some tapering as is illustrated in FIG. 2C due to the etching process used in forming the same; tapering is not however always present in the dielectric material pillar 21. In some embodiments, the dielectric material pillar 21 is a bilayer dielectric material fill structure (not shown) that includes an outer dielectric material layer located laterally adjacent to, and surrounding, an inner dielectric material layer. In the present application, the outer dielectric material layer is composed of a first dielectric material that is compositionally different from a second dielectric material that provides the inner dielectric material layer. The first and second dielectric materials that provide the outer dielectric material layer and the inner dielectric material layer, respectively, can include a silicon nitride based dielectric material such as, for example, silicon nitride, silicon boron carbon nitride, or a dielectric including atoms of Si, O, C and N, a silicon carbon based dielectric material such as, for example, silicon carbide or a dielectric including atoms of Si, C and O, or any other dielectric material such as, for example, silicon dioxide. In one example, outer dielectric material layer is composed of a dielectric including atoms of Si, C and O or silicon carbide, and the inner dielectric material layer is composed of silicon dioxide.

The at least one gate structure 22 and the backside gate contact extension 23 shown in FIGS. 2B and 2C, includes a gate dielectric material and a gate electrode, both of which are not separately shown, but intended to be within region defined by the gate structure 22. As is known to those skilled in the art, the gate dielectric material directly contacts a physically exposed surface(s) of each semiconductor channel material structure, and the gate electrode is formed on the gate dielectric material. Note that the gate structure 22 and the backside gate contact extension 23 that are present in region 101 are of unitary construction (i.e., a single work piece) and are composed of the same gate materials. The backside gate contact extension 23 is formed by forming an opening in the shallow trench extension structure 15 present in region 101 that physically exposes a surface of the second semiconductor material layer 14 and during gate structure 22 formation the backside gate contact extension 23 is formed into this opening.

The gate dielectric material of the gate structure 22 has a dielectric constant of 4.0 or greater. All dielectric constants mentioned herein are measured in a vacuum unless otherwise indicated. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOx), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as La, Al and/or Mg.

The gate electrode of the gate structure 22 can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the WFM-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to, Al, W, or Co.

In embodiments of the present application, and when multiple gate structures are present, each gate structure 22 can be include compositionally same and/or compositionally different gate dielectric materials and/or gate electrodes. In embodiments in which compositionally different gate structures 22 are formed, block mask technology can be implemented to form the same.

The pFET device source/drain regions 24 include a semiconductor material and a p-type dopant; note that each gate structure includes a first source/drain region located on one side of the gate structure and a second source/drain region located on a second side of the gate structure. The semiconductor material that provides the pFET device source/drain regions 24 includes one of the semiconductor materials mentioned above in providing the first semiconductor material layer 10. The semiconductor material that provides the pFET device source/drain regions 24 can be compositionally the same as, or compositionally different from, the semiconductor material that provides each semiconductor channel material nanosheet 16 The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium and indium. The concentration of the p-type dopant in the pFET device source/drain regions 24 can range from 1×10¹⁸ atoms/cm³ to 1×10²¹ atoms/cm³, although dopant concentrations greater than 1×10²¹ atoms/cm³ or less than 1×10¹⁸ atoms/cm³ are also conceived.

The nFET device source/drain regions 25 include a semiconductor material and an n-type dopant. The semiconductor material that provides the nFET device source/drain regions 25 includes one of the semiconductor materials mentioned above in providing the first semiconductor material layer 10. The semiconductor material that provides the nFET device source/drain regions 25 can be compositionally the same as, or compositionally different from, the semiconductor material that provides each semiconductor channel material nanosheet 16. N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. The concentration of n-type dopants in the nFET device source/drain regions 25 are within the range mentioned above for the pFET device source/drain regions 24.

The VBPR contact structures 27 include a via portion and a non-via portion; the non-via portion has a width that is greater than a width of the via portion. The non-via portion of the VBPR contact structure 27 in the pFET device region 102 contacts one of the pFET source/drain regions 24, while the VBPR contact structure 27 in the nFET device region 100 contacts one of the nFET device source/drain regions 25. The via portion of each VBPR contact structure 27 extends through the frontside ILD material layer 28 and entirely through one of the shallow trench isolation structures 15; each VBPR contact structure 27 lands on a surface of the second semiconductor material layer 14. Each VBPR contact structure 27 is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Jr, Rh, or an alloy thereof. The VBPR contact structures 27 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside ILD material layer 28 can be composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The source/drain contact structures 26, the first frontside metal via structures 30 and the second frontside metal via structures 31 can be composed of one of the materials (i.e., conductive contact materials, silicides and diffusion barrier materials) as mentioned above for the VBPR contact structures 27. Typically, the first frontside metal via structures 30 and the second frontside metal via structures 31 do not however include a silicide. In the present application, the first frontside metal via structures 30 are used for wiring the source/drain regions in each respective device region, while the second frontside metal via structures 31 are used for wiring the gate structure in each respective device region.

The frontside BEOL structure 32 can include one or more interconnect dielectric material layers (including one of the dielectric materials mentioned above for the frontside ILD material layer 28) that contain one or more wiring regions (the wiring regions can include any electrically conductive metal (e.g., Cu) or metal alloy, (e.g., Cu-AL) embedded therein. The carrier wafer 34 can include one of the semiconductor materials mentioned above for the first semiconductor material layer 10.

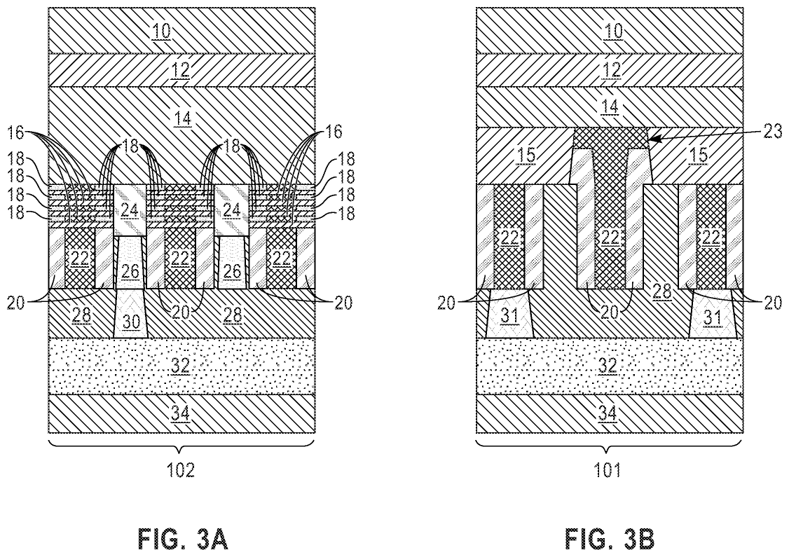

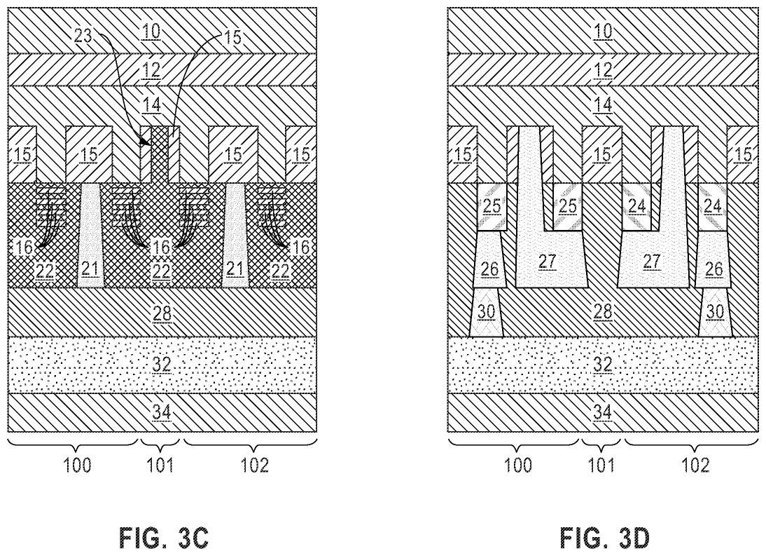

Referring now to FIGS. 3A, 3B, 3C and 3D, there are illustrated the exemplary structure shown in FIGS. 2A, 2B, 2C and 2D, respectively, after flipping the structure 180° to physically expose a backside of the substrate; i.e., the first semiconductor layer 10 of the substrate is physically exposed by this flipping step. This flipping step will allow backside processing of the exemplary structure. Backside processing occurs on a side of a wafer opposite the FETs. Flipping of the structure can be performed by hand or by utilizing a mechanical means such as, for example, a robot arm.

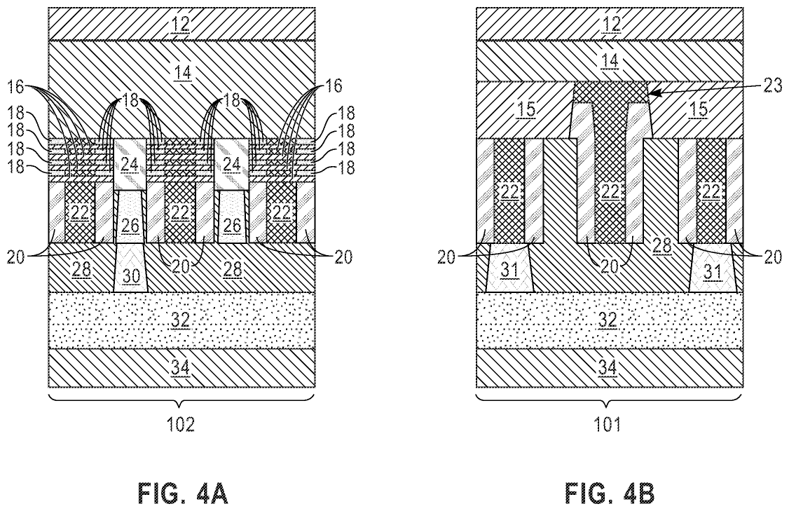

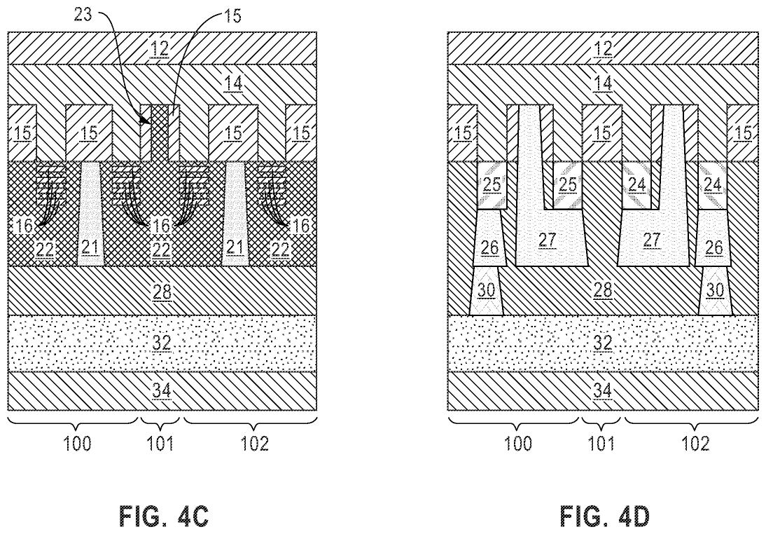

Referring now to FIGS. 4A, 4B, 4C and 4D, there are illustrated the exemplary structure shown in FIGS. 3A, 3B, 3C and 3D, respectively, after removing the first semiconductor material layer 10 of the substrate to physically expose the etch stop layer 12 of the substrate. The removal of the first semiconductor material layer 10 of the substrate can be performed utilizing a material removal process that is selective in removing the first semiconductor material that provides the first semiconductor material layer 10.

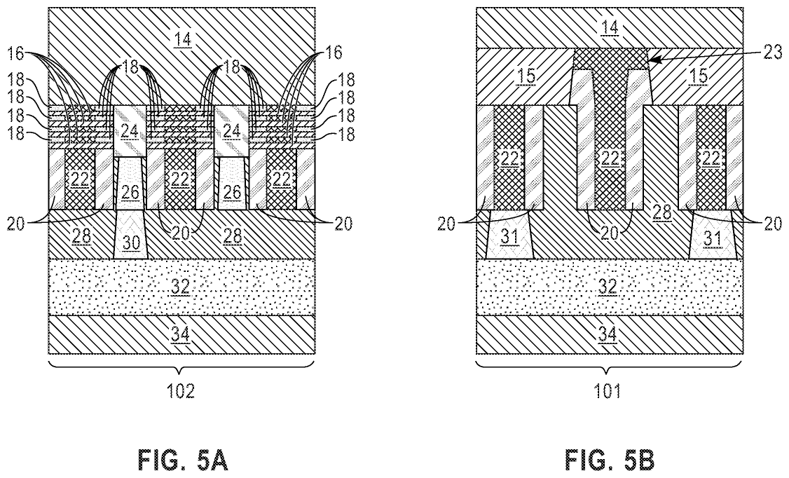

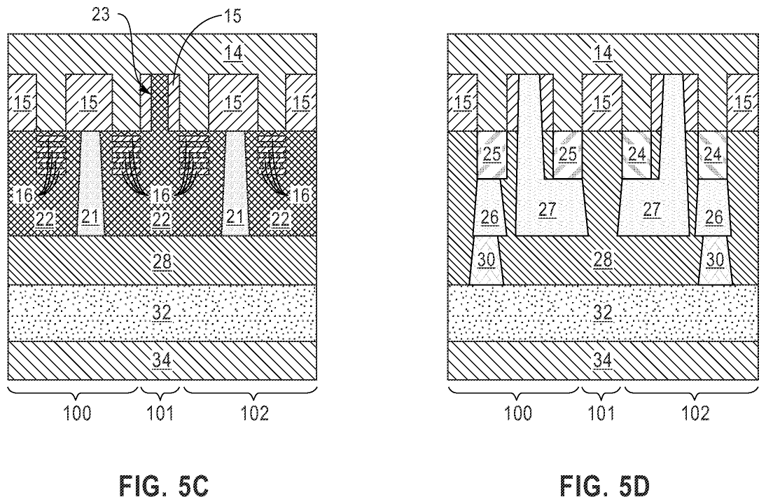

Referring now to FIGS. 5A, 5B, 5C and 5D, there are illustrated the exemplary structure shown in FIGS. 4A, 4B, 4C and 4D, respectively, after removing the physically exposed etch stop layer 12 of the substrate to physically expose the second semiconductor material layer 14 of the substrate. The removal of the etch stop layer 12 includes a material removal process that is selective in removing the etch stop layer 12.

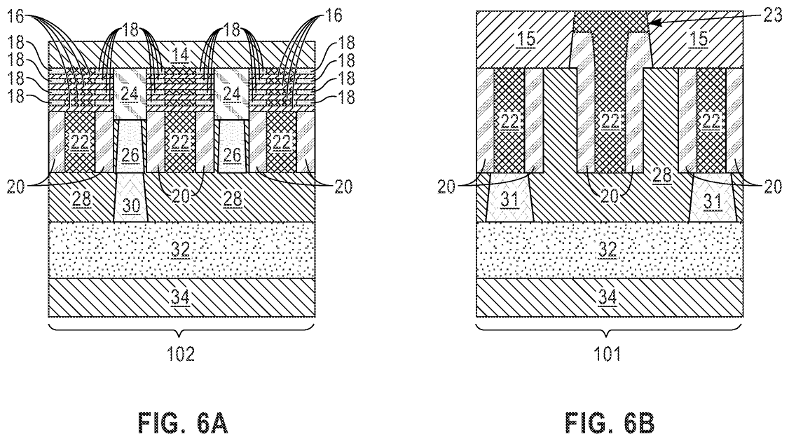

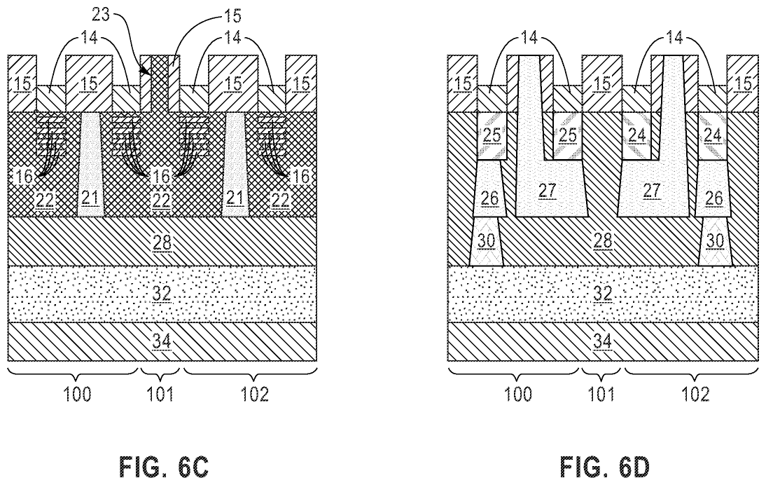

Referring now to FIGS. 6A, 6B, 6C and 6D, there are illustrated of the exemplary structure shown in FIGS. 5A, 5B, 5C and 5D, respectively, after recessing the physically exposed second semiconductor material layer 14 of the substrate to physically expose a surface of the backside gate contact extension 23 (See, for example, FIGS. 6B-6C). The recessing of the physically exposed second semiconductor material layer 14 of the substrate includes any recess etching process that is selective in removing the second semiconductor material that provides the second semiconductor material layer 14. Note that a portion of the second semiconductor material layer 14 remains in both the nFET device region 100 and the pFET device region 102 (See, for example, FIGS. 6A-6D). In some embodiments in which the substrate is composed of a single semiconductor material, only a recess etch can be employed to provide the structure shown in FIGS. 6A-6D.

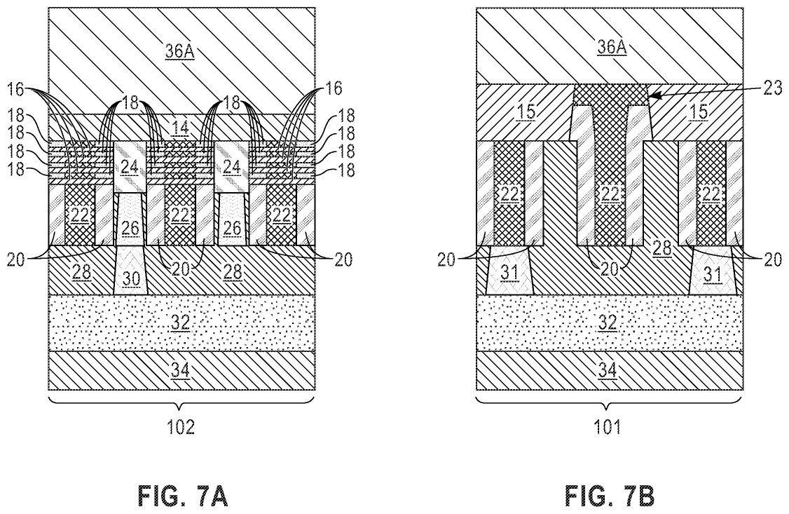

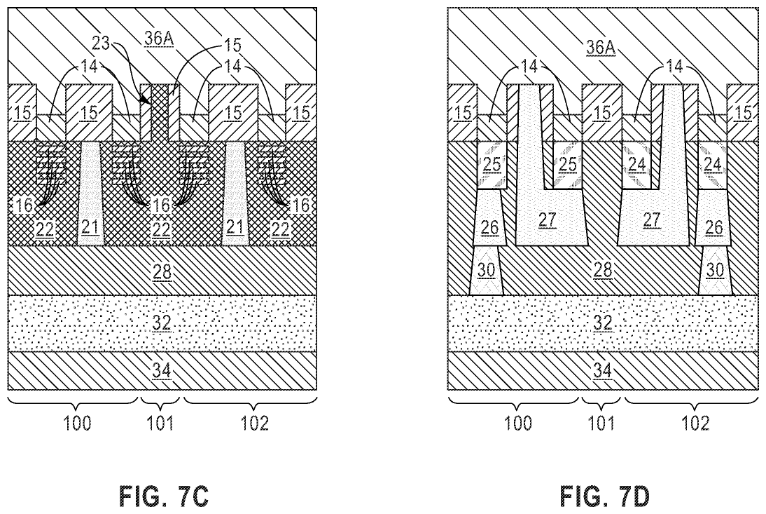

Referring now to FIGS. 7A, 7B, 7C and 7D, there are illustrated the exemplary structure shown in FIGS. 6A, 6B, 6C and 6D, respectively, after forming a first backside ILD material layer 36A. The first backside ILD material layer 36A can include one of the dielectric materials mentioned above for the frontside ILD material layer 28. The first backside ILD material layer 36A can be formed by a deposition process such as, for example, chemical vapor deposition (CVD), plasma enhanced chemical vapor deposition (PECVD) or spin-on coating.

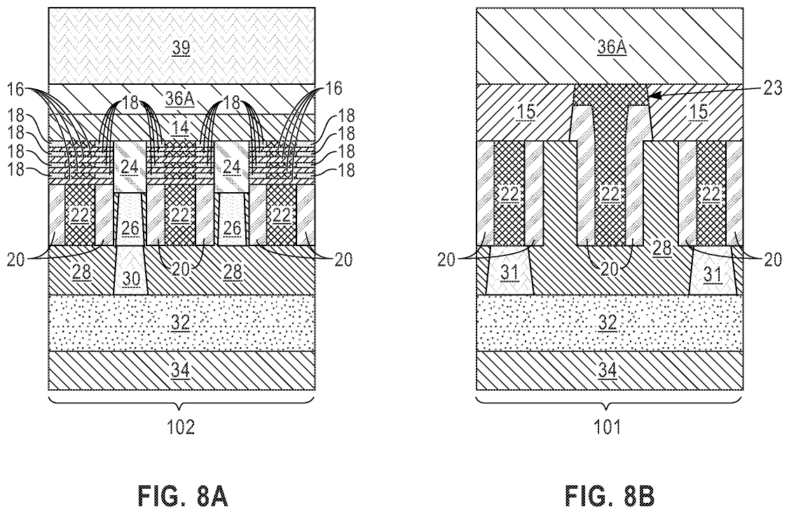

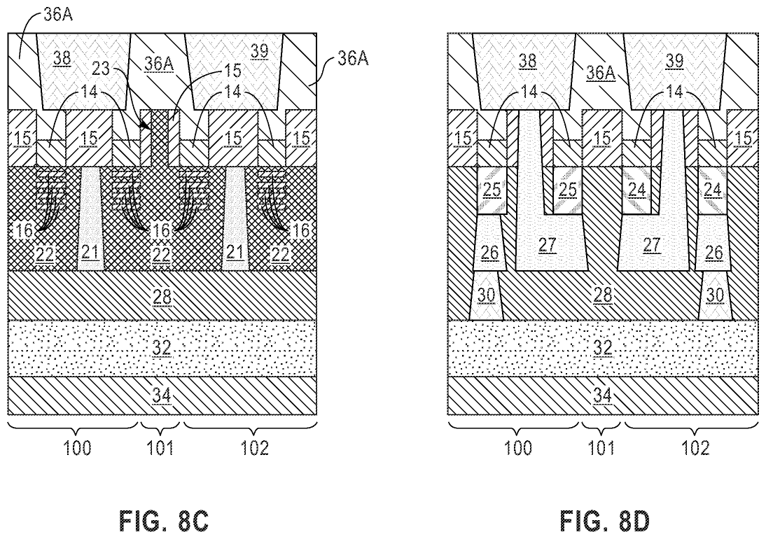

Referring now to FIGS. 8A, 8B, 8C and 8D, there are illustrated the exemplary structure shown in FIGS. 7A, 7B, 7C and 7D, respectively, after forming spaced apart backside power rails in the first backside interlayer dielectric material layer 36A. In accordance with the present application, a first backside power rail 38 of the spaced apart backside power rails is present in the nFET device region 100 and provides Vss power to the gate structure 22 in the nFET device region 100, and a second backside power rail 39 of the spaced apart backside power rails is present in the pFET device region 102 and provides Vdd power to the gate structure 22 in the pFET device region 102.

Each of first backside power rail 38 and the second backside power rail 39 is composed of an electrically conductive material including, but not limited to, W, Co, Ru, Al, Cu, Pt, Rh, or Pd, with a thin metal adhesion layer (such as TiN, TaN) typically being formed prior to the conductive metal deposition; for clarity, the metal adhesion layer is not separately illustrated in the drawings of the present application. The first backside power rail 38 and the second backside power rail 39 can be formed by forming backside power rail openings in the first backside ILD material layer 36A; each backside power rail opening physically exposes a surface of at least the VBPR contact structure 37 that is present in each of the device regions. The backside power rail openings are then filled with at least one of the electrically conductive materials mentioned above, and a planarization process can follow the filling of the backside power rail openings. The filling can include a CVD, PECVD, atomic layer deposition (ALD), sputtering or plating.

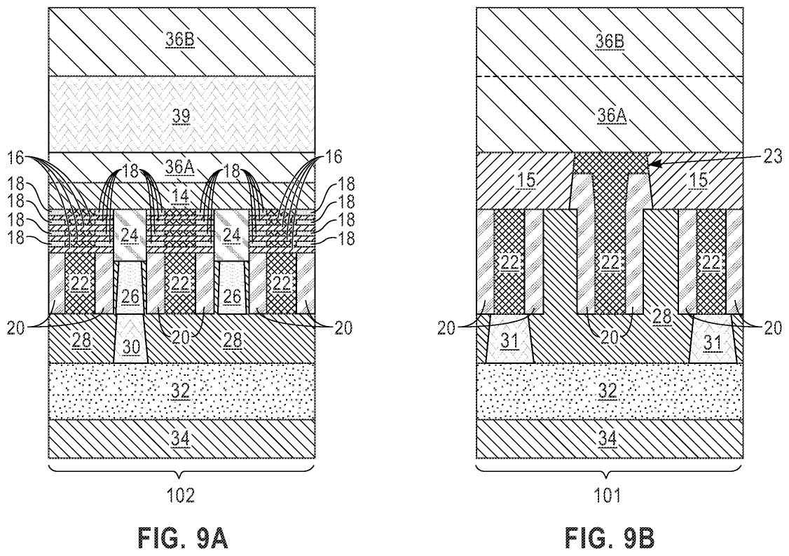

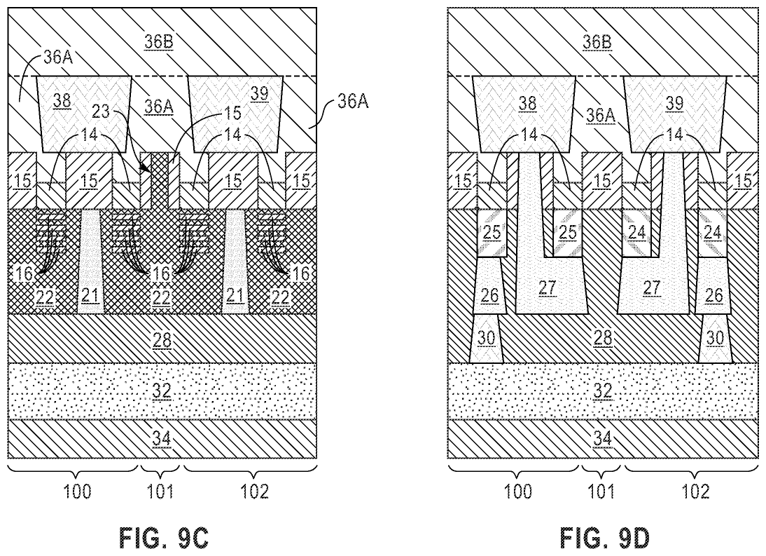

Referring now to FIGS. 9A, 9B, 9C and 9D, there are illustrated the exemplary structure shown in FIGS. 8A, 8B, 8C and 8D, respectively, after forming a second backside ILD material layer 36B. The second backside ILD material layer 36B can be composed of one of the dielectric materials mentioned above for the frontside ILD material layer 28. The dielectric material that provides the second backside ILD material layer 36B can be compositionally the same as, or compositionally different from, the dielectric material that provides the first backside ILD material layer 36A. In the drawings of the present application, a dotted line is shown between the first backside ILD material layer 36A and the second backside ILD material layer 36B. This dotted line represents a material interface that can exist between these two backside ILD material layers. The second backside ILD material layer 36B can be formed utilizing a deposition process including, for example, CVD, PECVD or spin-on coating.

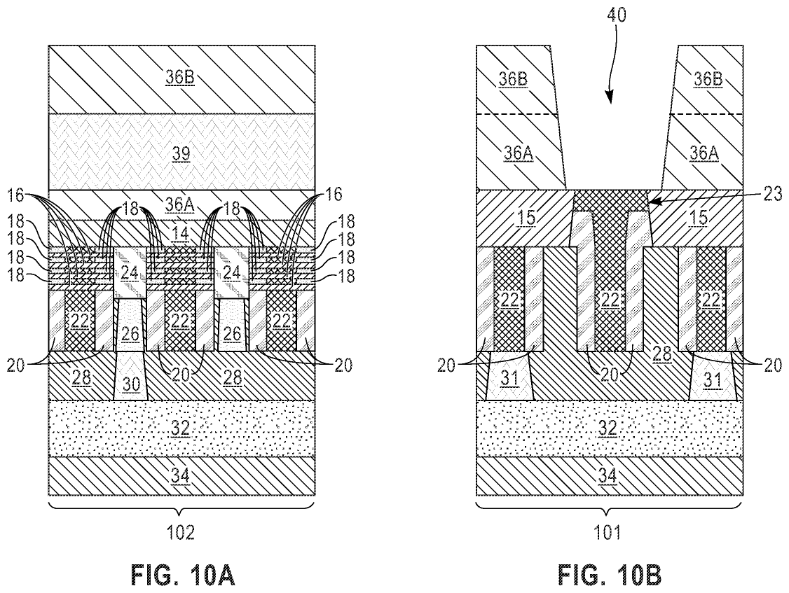

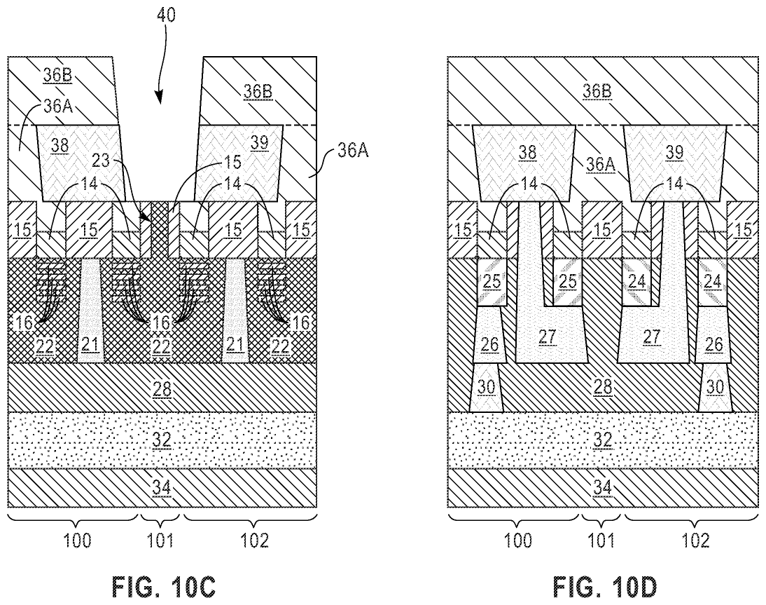

Referring now to FIGS. 10A, 10B, 10C and 10D, there are illustrated the exemplary structure shown in FIGS. 9A, 9B, 9C and 9D, respectively, after forming a backside skip-level via opening 40 in the second backside interlayer dielectric material layer 36B and the first backside interlayer dielectric material layer 36A, the backside skip-level via opening 40 physically exposing a surface of the backside gate contact extension 23. Note that the backside skip-level via opening 40 is formed predominately in region 101 of the structure. The backside skip-level via opening 40 can be formed by lithography and etching and this opening is formed between the first and second backside power rails 38 and 39 as is shown in FIG. 10C. Etching can include one of dry etching or chemical wet etching. In some embodiments of the present application, portions of each of the first and second power rails openings 38, 39 that are located in the area between the nFET device region and the pFET device region can be etched during this step of the present application.

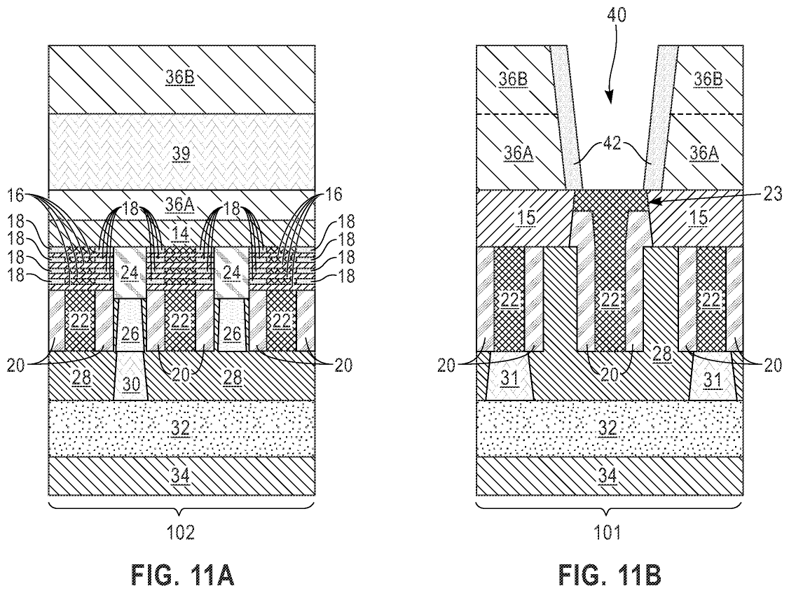

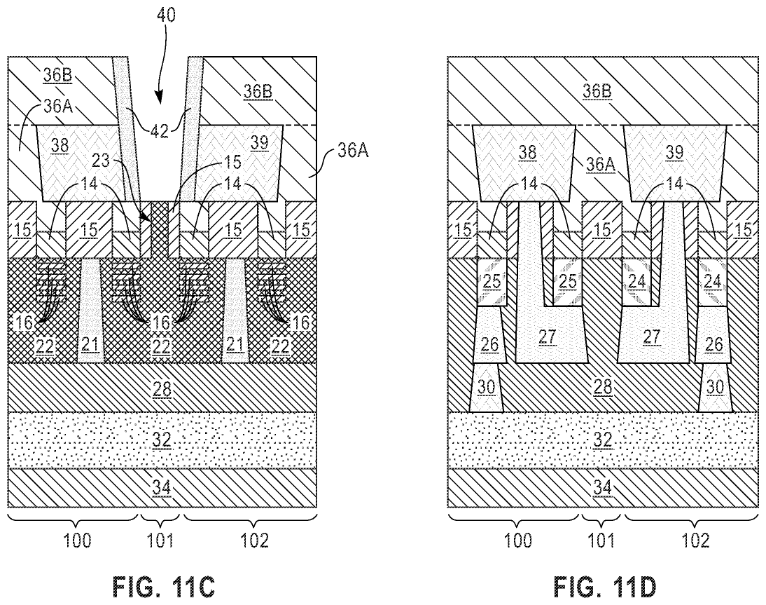

Referring now to FIGS. 11A, 11B, 11C and 11D, there are illustrated the exemplary structure shown in FIGS. 10A, 10B, 10C and 10D, respectively, after forming a dielectric spacer 42 in the backside skip-level via opening 40 and along physically exposed sidewalls of the second backside interlayer dielectric material layer 36B and the first backside interlayer dielectric material layer 36A. Dielectric spacer 42 includes one of the dielectric spacer materials mentioned above for the inner spacers 18. The dielectric spacer 42 can be formed by depositing the dielectric spacer material, followed by a spacer etch. As shown in FIG. 11C, the dielectric spacer 42 can be formed along physically exposed sidewalls of the spaced apart backside power rails (i.e., the first and second backside power rails 38, 39).

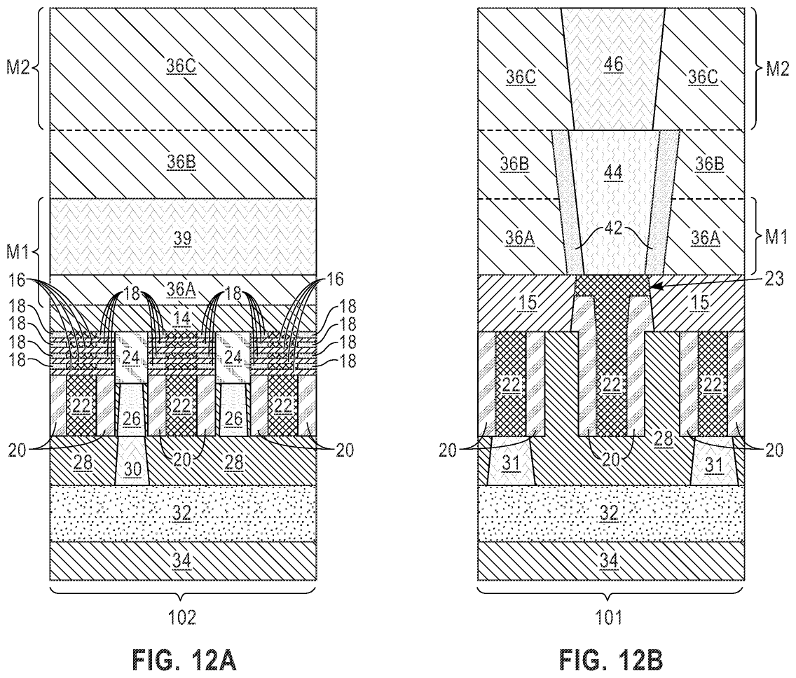

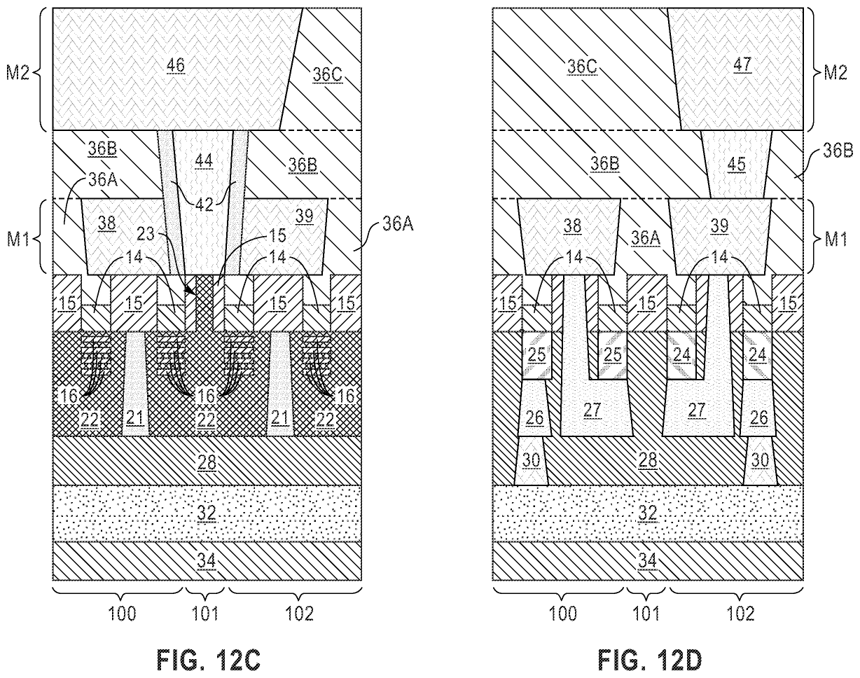

Referring now to FIGS. 12A, 12B, 12C and 12D, there are illustrated the exemplary structure shown in FIGS. 11A, 11B, 11C and 11D, respectively, after forming a backside skip-level through via 44 and a metal via structure 45, and a third backside interlayer dielectric material layer 36C including a backside signal line 46 contacting the backside skip-level through via 44 and an electrically conductive structure 47 (this structure can supply Vdd power to the device) contacting the metal via structure 45.

The backside skip-level through via 44 is formed in a remaining volume of the backside skip-level via opening 40 and between the dielectric spacer 42 as is shown in FIGS. 12B and 12C. As is also shown in these two drawings, the backside skip-level through via 44 contacts a surface of the backside gate contact extension 23, lands on a surface of the shallow trench isolation structure 15, and is present between the spaced apart backside power rails 38, 39. The backside skip-level through via 44 is however isolated from the spaced apart backside power rails 38, 39 by the dielectric spacer 42.

The backside skip-level through via 44 and the metal via structure 45 can include at least one of the electrically conductive materials mentioned above for the backside first and second power rails 38, 39. The backside skip-level through via 44 can be formed by filling the remaining volume of the backside skip-level through via opening 40 with an electrically conductive material as defined above, followed by planarization. The metal via structure 45 can be formed by forming a via opening by lithography and etching into the second backside ILD material layer 36B and then filling this metal via with an electrically conductive material as defined above for the backside power rails, followed by a planarization. In embodiments, the filling and planarization of the remaining volume of the backside skip-level via opening 40 and the via opening can be performed simultaneously. In other embodiments, the filling and planarization of the remaining volume of the backside skip-level via opening and the via opening can be performed in different steps utilizing block mask technology.

Next, the third backside ILD material layer 36C is formed. The third backside ILD material layer 36C is composed of one of the dielectric materials mentioned above for the frontside ILD material layer 28. The dielectric material that provides the third backside ILD material layer 36C can be compositionally the same as, or compositionally different from, the dielectric material that provides the second backside ILD material layer 36B. In the drawings of the present application, a dotted line is shown between the second backside ILD material layer 26B and the third backside ILD material layer 26C. This dotted line represents a material interface that can exist between these two backside ILD material layers. The third backside ILD material layer 36C can be formed utilizing a deposition process including, for example, CVD, PECVD or spin-on coating.

The backside signal line 46 and the electrically conductive structure 47 can be formed by forming openings in the third backside ILD material layer 36C and then filling those openings with an electrically conductive material as defined above for the backside power rails. A planarization process can follow the filling step.

Notably, FIGS. 12A-12D illustrate an exemplary semiconductor structure of the present application that includes gate structure 22 having backside gate contact extension 23, a first backside metal level M1 including spaced apart backside power rails (i.e., first and second backside power rails 38 and 39) located beneath the backside gate contact extension 23 of the gate structure 22 (seen when the structure shown in FIDS. 12A-12B is flipped 180°), a second backside metal level M2 is also present that includes backside signal line 46 located on the first backside metal level M2, and backside skip-level through via 44 is present connecting the backside signal line 46 to the backside gate contact extension 23 of the gate structure 22. As is shown, the backside skip-level through via 44 passes through the first backside metal level M1 and a portion of the backside skip-level through via 44 is located between the pair of spaced apart backside power rails 38, 39 that are present in the first backside metal level M1. In embodiments, dielectric spacer 42 is located on a sidewall of the backside skip-level through via 44, wherein the dielectric spacer 42 isolates the backside skip-level through via 44 from the pair of spaced apart backside power rails 38, 39 present in the first backside metal level M1.

In embodiments of the present application, the gate structure 22 including the backside gate contact extension 23 is a common gate structure that is present in nFET device region 100 and in pFET device region 102, wherein the gate structure in the nFET device region 100 is a component of a first nFET, and the gate structure 22 in the pFET device region 102 is component of a first pFET.

As is shown, first backside power rail 38 of the pair of spaced apart power rails is present in the nFET device region 100 and provides Vss power to the gate structure 22, and second backside power rail 39 of the pair of spaced apart backside power rails is present in the pFET device region 102 and provides Vdd power to the gate structure 22. Also, as is shown, the first backside power rail 38 is electrically connected to a first nFET device source/drain region 25 of the first nFET by one VBPR contact structure 27, and second backside power rail 39 is electrically connected to a first pFET device source/drain region 24 of the first pFET by another VBPR contact structure 27. As is even further shown, backside metal via structure 45 is present that electrically connects the second backside power rail 39 to electrically conductive structure 47 that is present in the second backside metal level M2.

The exemplary structure further includes frontside BEOL structure 32 and carrier wafer 34 located above the gate structure 22 (seen when flipping the structure shown in FIGS. 12A-12D 180°). The frontside BEOL structure 32 is electrically connected to a second nFET device source/drain region 25 of the first nFET by frontside source/drain contact structure 26 and first frontside metal via structure 30, and to a second pFET device source/drain region 24 of the first pFET by another frontside source/drain contact structure 26 and another frontside metal via structure 30.

In embodiments, the structure can further include a second nFET present in the nFET device region 100, and a second pFET present in the pFET device region 102. In such an embodiment, the second nFET is spaced apart from the first nFET by dielectric material pillar 21, and the second pFET is spaced apart from the second nFET by another dielectric material pillar 21.

As can be seen in the drawings of the present application, the backside skip-level through via 44 has a height that is taller than the height of the pair of spaced apart backside power rails 38, 39 that are present in the first backside metal level M1.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a gate structure having a backside gate contact extension;
a first backside metal level comprising a pair of spaced apart backside power rails and located beneath the backside gate contact extension of the gate structure;
a second backside metal level comprising a backside signal line and located on the first backside metal level; and
a backside skip-level through via connecting the backside signal line to the backside gate contact extension of the gate structure.

2. The semiconductor structure of claim 1, wherein the backside skip-level through via passes through the first backside metal level and a portion of the backside skip-level through via is located between the pair of spaced apart backside power rails that are present in the first backside metal level.

3. The semiconductor structure of claim 2, further comprising:
a dielectric spacer located on a sidewall of the backside skip-level through via, wherein the dielectric spacer isolates the backside skip-level through via from the pair of spaced apart backside power rails present in the first backside metal level.

4. The semiconductor structure of claim 1, wherein the gate structure is a common gate structure that is present in an n-type field effect transistor (nFET) device region and in a p-type field effect transistor (pFET) device region, wherein the gate structure in the nFET device region is a component of a first nFET, and the gate structure in the pFET device region is component of a first pFET.

5. The semiconductor structure of claim 4, wherein a first backside power rail of the pair of spaced apart backside power rails is present in the nFET device region and provides Vss power to the gate structure, and a second backside power rail of the pair of spaced apart backside power rails is present in the pFET device region and provides Vdd power to the gate structure, and a second.

6. The semiconductor structure of claim 5, wherein the first backside power rail is electrically connected to a first nFET device source/drain region of the first nFET by a first via-to-backside power rail (VBPR) contact structure, and the second backside power rail is electrically connected to a first pFET device source/drain region of the first pFET by a second VBPR contact structure.

7. The semiconductor structure of claim 6, further comprising:
a first backside metal via structure electrically connecting the first backside power rail to an electrically conductive structure that is present in the second backside metal level.

8. The semiconductor structure of claim 5, further comprising:
a frontside back-end-of-the-line (BEOL) structure located above the gate structure.

9. The semiconductor structure of claim 8, further comprising:
a carrier wafer located on the frontside BEOL structure.

10. The semiconductor structure of claim 8, wherein the frontside BEOL structure is electrically connected to a second nFET device source/drain region of the first nFET by a first frontside source/drain contact structure and a first frontside metal via structure, and to a second pFET device source/drain region of the first pFET by a second frontside source/drain contact structure, and a second frontside metal via structure.

11. The semiconductor structure of claim 5, wherein the gate structure in the nFET device region wraps around a plurality of vertically stacked semiconductor channel material nanosheets present in the nFET device region, and the gate structure in the pFET device region wraps around a plurality of vertically stacked semiconductor channel material nanosheets present in the pFET device region.

12. The semiconductor structure of claim 5, further comprising:
a second nFET present in the nFET device region, and a second pFET present in the pFET device region.

13. The semiconductor structure of claim 12, wherein the second nFET is spaced apart from the first nFET by a first dielectric material pillar, and the second pFET is spaced apart from the second nFET by a second dielectric material pillar.

14. The semiconductor structure of claim 1, wherein the gate structure and the backside gate contact extension are of unitary construction and are both composed of a gate dielectric material and a gate electrode.

15. The semiconductor structure of claim 1, wherein the pair of spaced apart backside power rails are present on a shallow trench isolation structure that is located beneath the gate structure.

16. The semiconductor structure of claim 1, wherein the pair of spaced apart backside power rails are present in a backside interlayer dielectric material layer, and the backside signal line is present in another backside interlayer dielectric material layer.

17. The semiconductor structure of claim 1, wherein the backside skip-level through via has a height that taller than the height of the pair of spaced apart backside power rails that are present in the first backside metal level.

18. The semiconductor structure of claim 1, wherein a portion of the backside gate contact extension is present in a shallow trench isolation structure.

19. The semiconductor structure of claim 1, further comprising:
a dielectric spacer present along an entirety of a sidewall of the gate structure and partially along a sidewall of the backside gate contact extension.

20. The semiconductor structure of claim 1, wherein the backside gate contact extension is present in an area that is located between an nFET device region and a pFET device region, and the gate structure is present in both the nFET device region and the pFET device region.
